(19) United States
(12) Patent Application Publication
(10) Pub. No.: US 2026/0351829 A1
(43) Pub. Date: Nov. 5, 2026

(54) TUNABLE MICROWAVE CIRCULATOR AND ASSOCIATED METHODS

(71) Applicant: THE REGENTS OF THE UNIVERSITY OF COLORADO, A BODY CORPORATE, Denver, CO (US)

(72) Inventors: LAILA MARZALL, Boulder (CO); ZORANA POPOVIC, Boulder, CO (US)

(21) Appl. No.: 19/484,776

(22) PCT Filed: May 15, 2024
(86) PCT No.: PCT/US2024/029488

§ 371 Date: Nov. 14, 2025

Related U.S. Application Data
(60) Provisional application No. 63/466,623, filed on May 15, 2023.

(51) Int. Cl. H01P 1/38; H03F 3/19

(52) U.S. Cl. CPC H01P 1/38; H03F 3/19

(57) ABSTRACT

A tunable microwave circulator has first, second, and third branches, each branch including a coupler, an amplifier, and a variable impedance circuit. Each coupler has an input port, a coupled port, a transmitted port, and an isolated port. In each branch, an input of the amplifier connects to the transmitted port and the variable impedance circuit connects to the isolated port. An output of the amplifier of the first branch connects to the coupled port of the coupler of the second branch, an output of the amplifier of the second branch connects to the coupled port of the coupler of the third branch, and the output of the amplifier of the third branch connects to the coupled port of the coupler of the first branch. Each variable impedance circuit may be adjusted to reduce mismatched impedance at the corresponding input ports.

### RELATED APPLICATION

This application claims priority to U.S. Provisional Patent Application No. 63/466,623, titled “Tunable Microwave Circulator,” filed May 15, 2023, which is incorporated herein by reference in its entirety.

### STATEMENT REGARDING FEDERALLY SPONSORED RESEARCH OR DEVELOPMENT

This invention was made with government support under grant number N00014-19-1-2487 awarded by the Office of Naval Research, and grant number 204303 awarded by the National Science Foundation. The government has certain rights in the invention.

### BACKGROUND

A circulator is a three-port non-reciprocal circuit component that is typically used in radio-frequency (i.e., microwave, millimeter wave, etc.) front ends for communications and sensing. A circulator may be placed between the transmitter, antenna, and receiver to reduce leakage of the transmitter into the receiver for full-duplex operation. Thus, the circulator enables the same antenna to be used for transmitting and receiving in the same frequency band.

### SUMMARY

Phased array antennas have transmit-receive modules in each antenna element. When the antenna beam is steered, especially over a large bandwidth, the antenna impedance changes from its nominal value (e.g., 50Ω). The transmitter power amplifier, connected to the antenna through the circulator, changes output impedance over frequency and power, as does the receiver low-noise amplifier. Typically, circulator parameters (e.g., isolation) change with varying port impedance.

The present embodiments include an active circulator that may be integrated in a semiconductor process, has a large bandwidth, and may have gain instead of loss. Any communication or sensing system that uses circulators may benefit from the present embodiments. Typically, at least 30 dB of isolation is needed between a transmitter and receiver at the same frequency to minimize self-interference. In many prior-art systems, switches are commonly used since there is no broadband component with this isolation level that may be integrated into the system. Therefore, same-frequency full-duplex operation is currently not possible with integrated front ends. The present embodiments make simultaneous transmit-receive operation possible with integrated solutions, over broad bandwidth, and with gain. This, in turn enables several applications, such as continuous surveillance in jamming systems, and efficient use of spectral allocations for communication.

Most prior-art circulators are made of ferrite materials and require a DC magnetic field from a permanent magnet, which is generally heavy, bulky, narrowband, and lossy. The ferrite and DC magnet prevent integration into a front end. Advantageously, the present embodiments do not use a magnet, may be implemented as a hybrid or monolithic planar circuit, and is easily integrated with other components. Monolithic implementations may be in a silicon, GaAs, GaN, or other type of semiconductor process. For example, for a high-power application that requires linearity in the receive chain, GaN would work well.

In certain embodiments, the techniques described herein relate to a tunable microwave circulator that includes: a first coupler having a first input port, a first coupled port, a first transmitted port, and a first isolated port; a first amplifier having an input connected to the first transmitted port; a first variable impedance circuit connected to the first isolated port; a second coupler having a second input port, a second coupled port connected to an output of the first amplifier, a second transmitted port, and a second isolated port; a second amplifier having an input connected to the second transmitted port; a second variable impedance circuit connected to the second isolated port; a third coupler having a third input port, a third coupled port connected to an output of the second amplifier, a third transmitted port, and a third isolated port; a third amplifier having an input connected to the third transmitted port and an output connected to the first coupled port; and a third variable impedance circuit connected to the third isolated port.

In certain embodiments, the techniques described herein relate to a tunable microwave circulator that includes: first, second, and third branches, each of the first, second, and third branches including: a coupler having an input port, a coupled port, a transmitted port, and an isolated port; an amplifier having an input connected to the transmitted port of the coupler; and a variable impedance circuit connected to the isolated port of the coupler; wherein: an output of the amplifier of the first branch is connected to the coupled port of the coupler of the second branch; an output of the amplifier of the second branch is connected to the coupled port of the coupler of the third branch; and an output of the amplifier of the third branch is connected to the coupled port of the coupler of the first branch.

In certain embodiments, the techniques described herein relate to a method for tuning any of the tunable microwave circulators described herein. The method includes: measuring an impedance of a first input port of a first coupler of the tunable microwave circulator; generating a correction signal based on the first impedance; and applying the first correction signal to the second variable impedance circuit of the microwave circulator.

### BRIEF DESCRIPTION OF THE FIGURES

FIG. 1 is a schematic of one example tunable microwave circulator, in embodiments.

FIG. 2 illustrates example use of the tunable microwave circulator of FIG. 1 with a reflectometer to measure an impedance mismatch, in embodiments.

FIG. 3 shows a table illustrating isoport corrections that correct for a plurality of impedance mismatches, in embodiments.

FIG. 4 shows a Smith chart of the impedance mismatches of FIG. 3, and a Smith chart of the isoport corrections of FIG. 3, in embodiments.

FIG. 5 is a schematic illustrating an example layout of the tunable microwave circulator of FIG. 1, in embodiments.

FIG. 6 is a schematic illustrating one example of first variable impedance circuit in further example detail, in embodiments.

FIG. 7 shows a table that defines configuration of the variable impedance circuits of FIG. 1 to apply a correction for an impedance mismatch, in embodiments.

FIG. 8 is a flowchart illustrating one example method for tuning a microwave circulator, in embodiments

### DETAILED DESCRIPTION

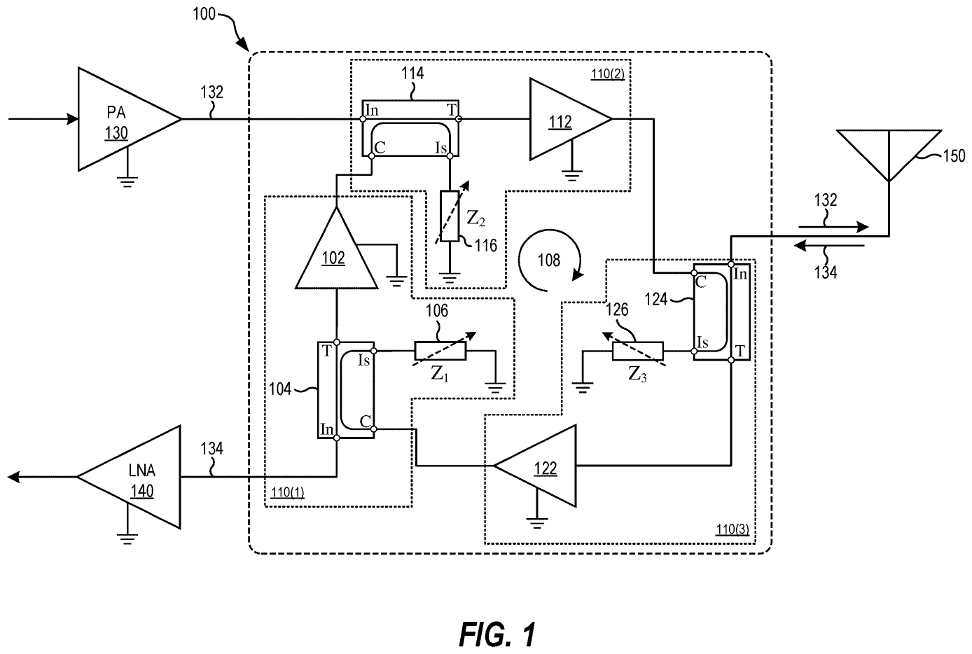

FIG. 1 is a schematic of a tunable microwave circulator 100, in accordance with the present embodiments. Circulator 100 has three “branches” that are, in general, similar to each other and connect to each other to form a loop 108. Specifically, a first branch 110(1) of the circulator 100 includes a first coupler 104, a first amplifier 102, and a first variable impedance circuit 106 whose impedance is denoted Z₁. Similarly, a second branch 110(2) of the circulator 100 includes a second coupler 114, a second amplifier 112, and a second variable impedance circuit 116 whose impedance is denoted Z₂. A third branch 110(3) of the circulator 100 includes a third coupler 124, a third amplifier 122, and a third variable impedance circuit 126 whose impedance is denoted Z₃.

Each of couplers 104, 114, and 124 is a four-port coupler with an input port (“In”), a coupled port (“C”), a through or transmitted port (“T”), and an isolated port (“Is”). The isolated port is also referred to herein as the “isoport.” In certain embodiments, first coupler 104, second coupler 114, and third coupler 124 are Lange couplers. In first branch 110(1), the input of first amplifier 102 is connected to the transmitted port of first coupler 104 and first variable impedance circuit 106 (Z₁) is connected to the isolated port of first coupler 104. In second branch 110(2), the input of second amplifier 112 is connected to the transmitted port of second coupler 114 and second variable impedance circuit 116 (Z₂) is connected to the isolated port of second coupler 114. In third branch 110(3), the input of third amplifier 122 is connected to the transmitted port of third coupler 124 and third variable impedance circuit 126 (Z₃) is connected to the isolated port of third coupler 124.

To complete the loop 108, the output of first amplifier 102 is connected to the coupled port of second coupler 114, the output of second amplifier 112 is connected to the coupled port of third coupler 124, and the output of third amplifier 122 is connected to the coupler port of first coupler 104. Note that the coupled ports of the couplers 104, 114, 124 serve as inputs, not outputs.

The input ports of the couplers 104, 114, and 124 are electrically connected to components outside of tunable microwave circulator 100. For example, FIG. 1 shows circulator 100 being used with a transceiver. Specifically, an antenna 150 is connected to the input port of second coupler 124, the output of a power amplifier (PA) 130 of a transmitter is connected to the input port of second coupler 114, and the input of a low-noise amplifier (LNA) 140 of a receiver is connected to the input port of first coupler 104. Note that in this embodiment, input ports of first coupler 104 and third coupler 124 are used as outputs. A transmission signal 132 from PA 130 passes through the second branch and part of third coupler 124 to feed antenna 150. A receiving signal 134 from antenna 150 passes through the third branch and part of first coupler 104 to feed LNA 140.

Couplers 104, 114, and 124 are, in general, not symmetric and their coupling ratios may be designed accounting for the gains of amplifiers 102, 112, and 122 to obtain a desired isolation. When each of the input ports is terminated at its nominal impedance (e.g., 50Ω) and the isolation is maximized across a frequency band, performance degrades when the input-port impedance changes. Advantageously, circulator 100 includes variable impedance circuits 106, 116, and 126 (e.g., impedances Z₁, Z₂, and Z₃) that are independently tunable to achieve one or more performance metrics (e.g., isolation, match, gain, etc.).

Antenna 150 in FIG. 1 may represent a single antenna, a stand-alone antenna, or one element of an antenna array. In the latter case, coupling of the antenna 150 to neighboring elements may change the impedance of antenna 150. In this case, antenna 150 may no longer be impedance-matched to the input port of third coupler 124. Where this impedance mismatch is not too large, first variable impedance circuit 126 (Z₁) may be adjusted to eliminate this mismatch, thereby restoring impedance matching between these two components.

Similarly, an impedance mismatch between LNA 140 and the input port of first coupler 104 may be primarily eliminated by controlling second variable impedance circuit 116 (Z₂). Similarly, an impedance mismatch between PA 130 and the input port of second coupler 114 may be primarily eliminated by controlling third variable impedance circuit 126 (Z₃). In this regard, the variable impedance circuit that has the greatest effect on mismatch between an external component and an input port of the circulator 100 is the variable impedance circuit located in the branch following the one to which the external component connects.

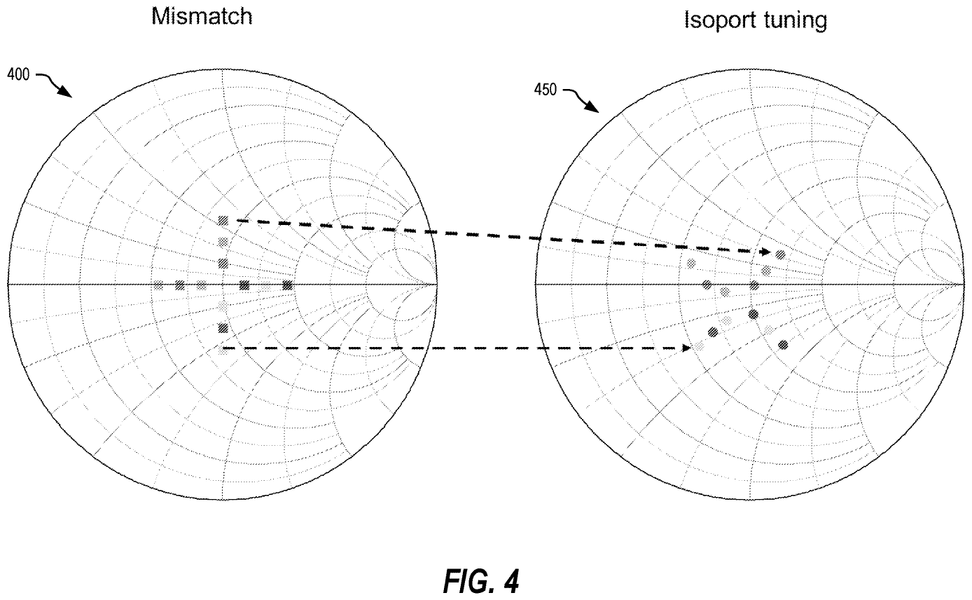

One aspect of the present embodiments includes the realization that there is a one-to-one correspondence between (i) the impedance mismatch between an external component and the input port of circulator 100 to which the external component is connected and (ii) a correction or adjustment to the variable impedance circuit located in the branch opposite to the connection to the external component. This one-to-one correspondence, which only exists under the assumption that the impedance mismatch is not too large, ensures that for any impedance mismatch, there also exists a unique correction that may be applied to the corresponding variable impedance circuit to eliminate the impedance mismatch (see FIG. 4). When the impedance mismatch is too large, adjustments to the other two variable impedance circuits also may be needed to fully eliminate the impedance mismatch.

Circulator 100 may be symmetric (e.g., where all three branches are identically constructed), partially asymmetric (e.g., where two of the three branches are identically constructed) or fully asymmetric (e.g., where all three branches are different). Each of couplers 104, 114, and 124 may be asymmetric or symmetric. Couplers 104, 114, and 124 may be different from each other or may be identical. Each of amplifiers 102, 112, and 122 may be single-stage or multi-stage, high-power or low-power, low-noise, high-gain, etc. Advantageously, each of the three branches may be designed, adjusted, and biased independently for best performance of circulator 100 for a given application. Further, circulator 100 is scalable in frequency, bandwidth, and power.

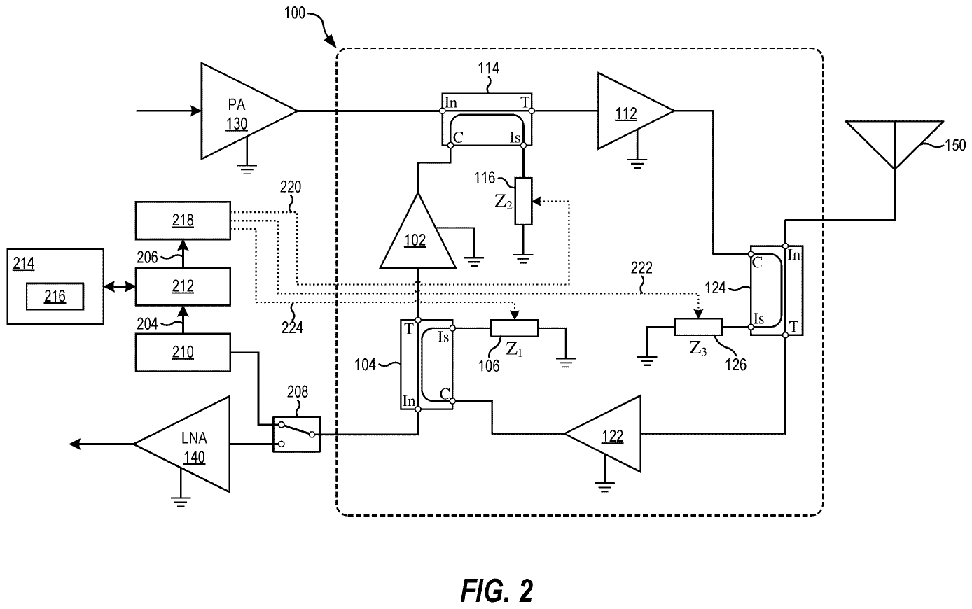

FIG. 2 illustrates use of tunable microwave circulator 100 of FIG. 1 with a reflectometer 210 to measure an impedance mismatch between LNA 140 and the input port of first coupler 104 without having to physically disconnect LNA 140 from circulator 100, in embodiments. Reflectometer 210 may also be referred to as an impedance sensor. A switch 208 connects the input port of first coupler 104 to reflectometer 210, which measures the impedance of this input port using reflectometry techniques known in the art. For example, switch 208 may connect the input port to a transmission line reflectometer that measures the impedance using a segment of transmission line that is sampled, at various points, with a plurality of varactor diodes (see D. T. Donahue and T. W. Barton, “Multi-port Reflectometry Applied to a Varactor-Tuned Sampled-Line,” 2020 95th ARFTG Microwave Measurement Conference (ARFTG), Los Angeles, CA, USA, 2020, pp. 1-4). In another example, reflectometer 210 transmits, to circulator 100, a sinusoidal signal at a single frequency. Reflectometer 210 then measures the amplitude and phase shift of the reflection (e.g., the complex reflection coefficient Γ), from which it determines the impedance at the single frequency. Other reflectometry techniques may be used without departing from the scope hereof.

Reflectometer 210 outputs a measured impedance signal 204 indicating the measured impedance to a signal processor 212, which processes measured impedance signal 204 to determine a measured impedance mismatch between the input port and the input of LNA 140. Signal processor 212 then determines, based on the measured impedance mismatch, one or more corrections to be applied to one or more of the variable impedance circuits 106, 116, and 126 (e.g., Z₁, Z₂, and Z₃) to correct for the impedance mismatch.

In some embodiments, signal processor 212 determines the one or more corrections by accessing an external memory 214 storing a look-up table (LUT) 216. Each entry of LUT 216 may, for example, stores corrections in association with a particular pre-determined impedance mismatch. Signal processor 212 selects an entry of LUT 216 that indicates a pre-determined impedance mismatch closest to the impedance mismatch derived from measured impedance signal 204. From that entry in LUT 216, the one or more corrections are retrieved and returned to the signal processor 212.

Signal processor 212 transmits a correction signal 206, based on the one or more retrieved corrections, to a controller 218 that adjusts one or more of variable impedance circuits 106, 116, and 126 (e.g., Z₁, Z₂, and Z₃) accordingly. In one embodiment, controller 218 only adjusts third variable impedance circuit 126 (Z₃) via a third control signal 224. In another embodiment, the controller 218 adjusts all three of impedance circuits 106, 116, and 126 (e.g., Z₁, Z₂, and Z₃) via a first control signal 220, a second control signal 222, and third control signal 224, respectively. For example, each of first control signal 220, second control signal 222, and third control signal 224 may set an impedance of first variable impedance circuit 106, variable impedance circuit 116, and variable impedance circuit 126, respectively. After the variable impedance circuits have been updated, switch 208 may be controlled to electrically connect the input of LNA 140 to the input port of first coupler 104.

In certain embodiments, signal processor 212 determines the corrections by processing the measured impedance signal 204 according to a model, as opposed to using LUT 216. Signal processor 212 may be a hard-wired circuit (e.g., a field-programmable gate array), a processor (e.g., microprocessor, CPU core, GPU, etc.) that executes machine-readable instructions, or a combination thereof (e.g., system-on-chip).

As an alternative to switch 208, reflectometer 210 may be electrically connected to the input port of the first coupler 104 via a directional coupler. In this case, switch 208 is omitted. The use of the additional directional coupler may introduce additional loss.

Although not shown in FIG. 2, a second reflectometer similar to reflectometer 210 may be used to measure the impedance of the input port of second coupler 114. Similarly, a third reflectometer, also similar to reflectometer 210, may be used to measure the impedance of the input port of second coupler 114. In this embodiment, all three measured input impedances may be communicated to signal processor 212 such that signal processor 212 controls controller 218 to update all three variable impedance circuits 106, 116, and 126 (e.g., Z₁, Z₂, and Z₃) to reduce impedance mismatches at all three of the input ports of circulator 100. In another embodiment, only two of the input impedances are measured to update two or three of variable impedance circuits 106, 116, and 126 (e.g., two or three of Z₁, Z₂, and Z₃).

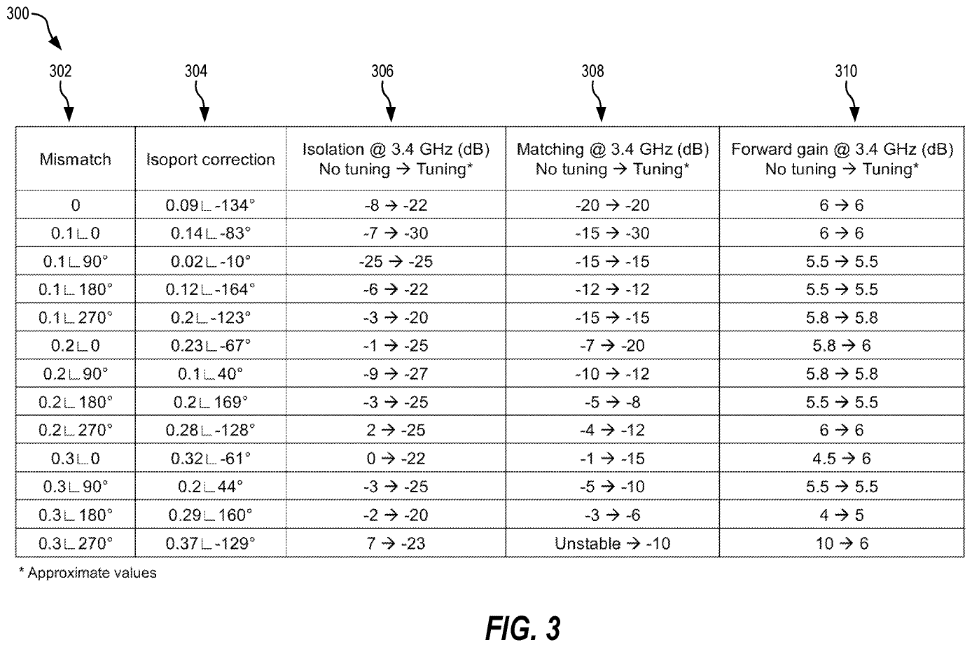

FIG. 3 shows a table 300 illustrating isoport corrections 304 that correct for a plurality of impedance mismatches 302. The table 300 may be used to construct LUT 216 of FIG. 2, to design circulator 100, or both. Table 300 may be derived from numerical simulations of circulator 100, direct measurements of circulator 100, or both. The impedance mismatches 302 have been transformed into complex reflection coefficients, being normalized to the characteristic impedance of the input port. The isoport impedances 304 have also been transformed into complex reflection coefficients, being normalized to the characteristic impedance of the isoport. Thus, the impedance mismatches 302 and isoport corrections 304 are in a form for plotting on Smith charts (e.g., see FIG. 4).

Table 300 also lists changes in isolation 306, changes in matching 308, and changes in forward gain 310 at 3.4 GHz. For example, for a mismatch 302 of 0.2 └90° and corresponding isoport correction of 0.1 └40°, isolation 406 improves from −9 dB to −27 dB, matching 408 improves from −10 dB to −12 dB, and forward gain 410 remains unchanged at 5.8 dB. The isoport corrections 304 in table 300 were selected by numerically optimizing the performance of circulator 100 to simultaneously achieve, for all of impedance mismatches 302, isolation less than −15 dB and matching less than −6 dB.

FIG. 4 shows a Smith chart 400 of the impedance mismatches 302 of table 300 of FIG. 3, and a Smith chart 450 of the isoport corrections 304 of table 300. Importantly, there is a one-to-one correspondence between the impedance mismatches 302 and the isoport corrections 304. Due to this correspondence, techniques like curve fitting and interpolation may be used to derive isoport corrections for impedance mismatches that are not listed in table 300. Such techniques may be implemented by signal processor 212 of FIG. 2.

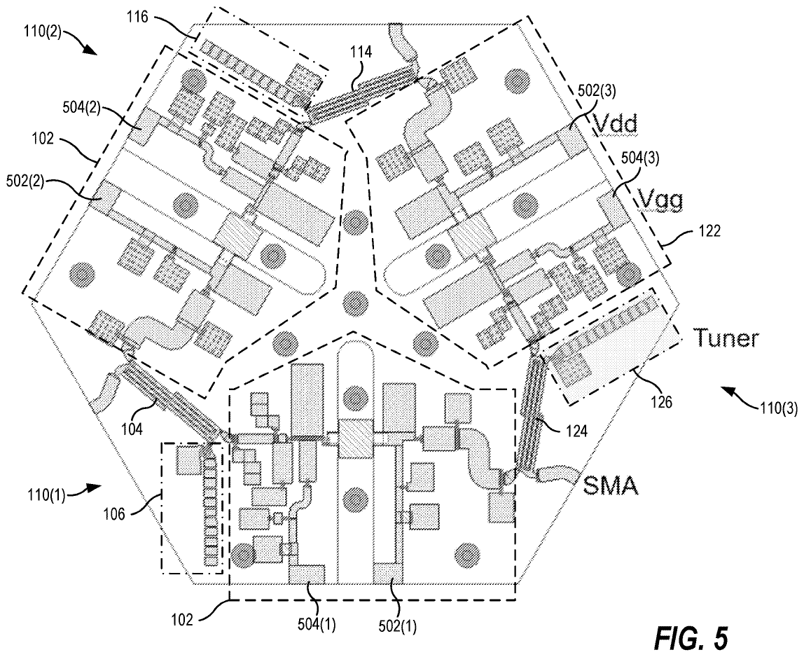

FIG. 5 is a schematic illustrating an example layout 500 of circulator 100 of FIG. 1, in embodiments. As shown, each branch 110(1)-(3) of circulator 100 has power connections Vdd 502(1)-(3) and Vgg 504(1)-(3) that provides power to first amplifier 102, second amplifier 112, and third amplifier 122, respectively. As shown, first amplifier 102, second amplifier 112, and third amplifier 122 each include components for biasing, impedance matching, and feedback.

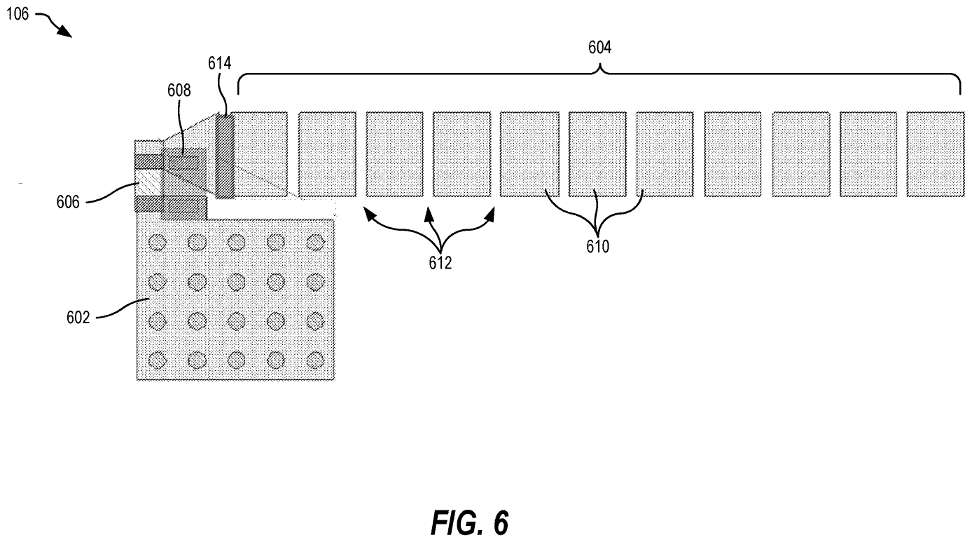

FIG. 6 is a schematic illustrating one example of first variable impedance circuit 106 in further example detail, in embodiments. Variable impedance circuits 116 and 126 are similar. In this example, variable impedance circuit 106 is manually tuned based on mismatch 302 of LUT 300 of FIG. 3 and defined equivalent resistance 306, inductance 308, and capacitance 310, for example.

First variable impedance circuit 106 includes a ground plane 602 and a stub 604 that are coupled together by a first component 606 and an optional second component 608. Stub 604 is formed of a plurality of pads 610 separated by gaps 612 that may be joined together by bridging the gaps with an electrical conductor 614, such as solder. Advantageously, the designer, after determining an impedance mismatch, may add or change one or both of components 606 and 608 and bridge zero or more gaps 612 using electrical conductor 614. For example, each of first component 606 and second component 608 may be one of a resistor, a capacitor, and an inductor.

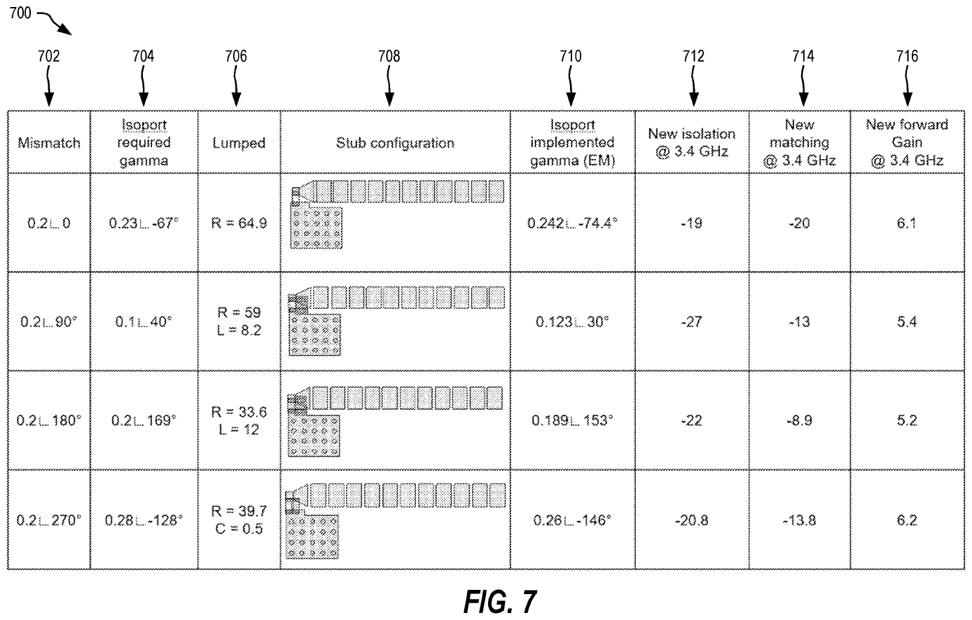

FIG. 7 shows a table 700 that defines configuration of variable impedance circuits 106, 116, 126 to apply a correction for an impedance mismatch 702 to circulator 100 of FIG. 1, in embodiments. Table 700 includes impedance mismatch 702 with corresponding isoport required gamma 704, components 706, stub configuration 708, isoport implemented gamma 710, achieved isolation 712 at 3.4 GHz, achieved matching 714 at 3.4 GHz, and achieved forward gain 716 at 3.4 GHz. Here, “gamma” refers to complex reflection coefficient. For example, for an impedance mismatch 702 of 0.2 └90° an isoport correction of 0.1 └40° is required. Table 700 indicates that components 706 of a 59Ω resistor and a 8.2 μH inductor with no filled gaps 612 of stub 604 would implement an isoport gamma of 0.123 └30° with isolation 712 of −27 dB, matching 714 of −13 dB, and gain 716 of 5.4 dB.

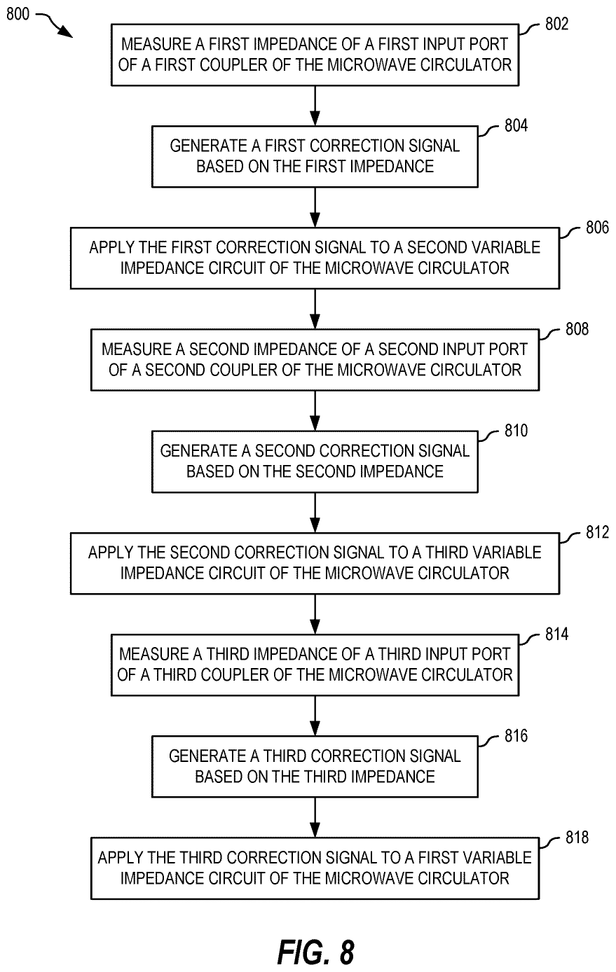

FIG. 8 is a flowchart illustrating one example method 800 for tuning a tunable microwave circulator, in embodiments. Method 800 may be implemented at least in part within signal processor 212 of FIG. 2.

In block 802, method 800 measures a first impedance of a first input port of a first coupler of the tunable microwave circulator. In one example of block 802, reflectometer 210 measures an impedance of the input port of first coupler 104 of tunable microwave circulator 100 of FIG. 1. In block 804, method 800 generates a first correction signal based on the first impedance. In one example of block 804, signal processor 212 of FIG. 2 processes measured impedance signal 204 and generates correction signal 206. In block 806, method 800 applies the first correction signal to a second variable impedance circuit of the microwave circulator. In one example of block 806, controller 218 of FIG. 2 applies first control signal 220 to second variable impedance circuit 116.

In block 808, method 800 measures a second impedance of a second input port of a second coupler of the tunable microwave circulator. In one example of block 808, a second reflectometer similar to reflectometer 210 of FIG. 2 measures an impedance of the input port of second coupler 114. In block 810, method 800 generates a second correction signal based on the second impedance. In one example of block 810, signal processor 212 of FIG. 2 processes measured impedance signal 204 from the second reflectometer and generates correction signal 206. In block 812, method 800 applies the second correction signal to a third variable impedance circuit of the tunable microwave circulator. In one example of block 812, controller 218 of FIG. 2 applies second control signal 222 to third variable impedance circuit 126.

In block 814, method 800 measures a third impedance of a third input port of a third coupler of the microwave circulator. In one example of block 814, a third reflectometer similar to reflectometer 210 of FIG. 2 measures an impedance of the input port of third coupler 124. In block 816, method 800 generates a third correction signal based on the third impedance. In one example of block 816, signal processor 212 of FIG. 2 processes measured impedance signal 204 from the third reflectometer and generates correction signal 206. In block 818, method 800 applies the third correction signal to a first variable impedance circuit of the microwave circulator. In one example of block 818, controller 218 of FIG. 2 applies third control signal 224 to first variable impedance circuit 106.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

### Combination of Features

Features described above as well as those claimed below may be combined in various ways without departing from the scope hereof. The following examples illustrate possible, non-limiting combinations of features and embodiments described above. It should be clear that other changes and modifications may be made to the present embodiments without departing from the spirit and scope of this invention:
(A1) A tunable microwave circulator includes: a first coupler having a first input port, a first coupled port, a first transmitted port, and a first isolated port; a first amplifier having an input connected to the first transmitted port; a first variable impedance circuit connected to the first isolated port; a second coupler having a second input port, a second coupled port connected to an output of the first amplifier, a second transmitted port, and a second isolated port; a second amplifier having an input connected to the second transmitted port; a second variable impedance circuit connected to the second isolated port; a third coupler having a third input port, a third coupled port connected to an output of the second amplifier, a third transmitted port, and a third isolated port; a third amplifier having an input connected to the third transmitted port and an output connected to the first coupled port; and a third variable impedance circuit connected to the third isolated port.
(A2) In the tunable microwave circulator denoted (A1), each of the first, second, and third couplers is a Lange coupler.
(A3) In either of the tunable microwave circulators denoted (A1) and (A2), at least one of the first, second, and third variable impedance circuits includes a varactor diode.
(A4) In any of the tunable microwave circulators denoted (A1) to (A3), the tunable microwave circulator further includes: an impedance sensor configured to measure an impedance of the first input port and output a impedance signal indicative of the impedance of the first input port; a signal processor configured to process the impedance signal to generate a correction signal; and a controller configured to output a control signal, based on the correction signal, to the second variable impedance circuit to control an impedance of the second variable impedance circuit.
(A5) In the tunable microwave circulator denoted (A4), the impedance sensor includes a reflectometer.
(A6) In the tunable microwave circulator denoted (A5), the reflector includes a transmission line, a plurality of varactor diodes connected to the transmission line to sample the transmission line, and an analog-to-digital converter configured to digitize a signal outputted by each of the plurality of varactor diodes.
(A7) In the tunable microwave circulator denoted (A6), the tunable microwave circulator further includes a switch. The switch, when in a first position, connects the first input port to the transmission line. The switch, when in a second position, connects the first input port to an external load.
(A8) In any of the tunable microwave circulators denoted (A4) to (A7), the signal processor includes a memory storing a look-up table. The signal processor is configured to process the impedance signal to determine an impedance mismatch between the impedance of the first input port, as measured by the impedance sensor, and a nominal impedance of the first input port. The signal processor is also configured to retrieve, based on the impedance mismatch, the correction signal from the look-up table.
(A9) In the tunable microwave circulator denoted (A8), the signal processor includes a field-programmable gate array in communication with the memory.
(A10) In the tunable microwave circulator denoted (A8), the signal processor includes a microprocessor in communication with the memory. The memory stores machine-readable instructions that, when executed by the microprocessor, control the signal processor to process the impedance signal and retrieve the impedance correction.
(A11) In any of the tunable microwave circulators denoted (A1) to (A10), the tunable microwave circulator includes: a first impedance sensor configured to measure a first impedance of the first input port and output a first impedance signal indicative of the first impedance; a signal processor configured to process the first impedance signal to generate a first correction signal; a first controller configured to output a first control signal, based on the first correction signal, to the second variable impedance circuit to control an impedance of the second variable impedance circuit; a second impedance sensor configured to measure a second impedance of the second input port and output a second impedance signal indicative of the second impedance, the signal processor being configured to process the second impedance signal to generate a second correction signal; and a second controller configured to output a second control signal, based on the second correction signal, to the third variable impedance circuit to control an impedance of the third variable impedance circuit.
(A12) In the tunable microwave circulator denoted (A11), each of the first and second impedance sensors includes a reflectometer.
(A13) In either of the tunable microwave circulators denoted (A11) and (A12), the signal processor includes a memory storing a look-up table. The signal processor is configured to (i) process the first impedance signal to determine a first impedance mismatch between the first impedance of the first input port, as measured by the first impedance sensor, and a first nominal impedance of the first input port, (ii) retrieve, based on the first impedance mismatch, the first correction signal from the look-up table, (iii) process the second impedance signal to determine a second impedance mismatch between the second impedance of the second input port, as measured by the second impedance sensor, and a second nominal impedance of the second input port, and (iv) retrieve, based on the second impedance mismatch, the second correction signal from the look-up table.
(A14) In any of the tunable microwave circulators denoted (A11) to (A13), the tunable microwave circulator further includes a third impedance sensor configured to measure a third impedance of the third input port and output a third impedance signal indicative of the third impedance, the signal processor being configured to process the third impedance signal to generate a third correction signal. The tunable microwave circulator further includes a third controller configured to output a third control signal, based on the third correction signal, to the first variable impedance circuit to control an impedance of the first variable impedance circuit.
(A15) In the tunable microwave circulator denoted (A14), each of the first, second, and third impedance sensors includes a reflectometer.
(A16) In either of the tunable microwave circulators denoted (A14) and (A15), the signal processor includes a memory storing a look-up table. The signal processor is configured to (i) process the first impedance signal to determine a first impedance mismatch between the first impedance of the first input port, as measured by the first impedance sensor, and a first nominal impedance of the first input port, (ii) retrieve, based on the first impedance mismatch, the first correction signal from the look-up table, (iii) process the second impedance signal to determine a second impedance mismatch between the second impedance of the second input port, as measured by the second impedance sensor, and a second nominal impedance of the second input port, (iv) retrieve, based on the second impedance mismatch, the second correction signal from the look-up table, (v) process the third impedance signal to determine a third impedance mismatch between the third impedance of the third input port, as measured by the third impedance sensor, and a third nominal impedance of the third input port, and (vi) retrieve, based on the third impedance mismatch, the third correction signal from the look-up table.
(A17) In any of the tunable microwave circulators denoted (A1) to (A16), the tunable microwave circulator further includes a first controller configured to output a first control signal to the second variable impedance circuit to set an impedance of the second variable impedance circuit, a second controller configured to output a second control signal to the third variable impedance circuit to set an impedance of the third variable impedance circuit, and a third controller configured to output a third control signal to the first variable impedance circuit to set an impedance of the first variable impedance circuit.
(A18) In any of the tunable microwave circulators denoted (A1) to (A17), the tunable microwave circulator further includes a receiver connected to one of the first, second, and third input ports.
(A19) In any of the tunable microwave circulators denoted (A1) to (A18), the tunable microwave circulator further includes a transmitter connected to one of the first, second, and third input ports.
(A20) In any of the tunable microwave circulators denoted (A1) to (A19), the tunable microwave circulator further includes an antenna connected to one of the first, second, and third input ports.
(A21) In the tunable microwave circulator denoted (A20), the antenna is an element of an antenna array.
(B1) A tunable microwave circulator includes first, second, and third branches. Each of the first, second, and third branches includes: a coupler having an input port, a coupled port, a transmitted port, and an isolated port; an amplifier having an input connected to the transmitted port of the coupler; and a variable impedance circuit connected to the isolated port of the coupler. An output of the amplifier of the first branch is connected to the coupled port of the coupler of the second branch. An output of the amplifier of the second branch is connected to the coupled port of the coupler of the third branch. An output of the amplifier of the third branch is connected to the coupled port of the coupler of the first branch.
(C1) A method includes measuring an impedance of the first input port of any of the tunable microwave circulators denoted (A1) to (A21) and (B1). The method also includes generating a correction signal based on the impedance. The method also includes applying the correction signal to the second variable impedance circuit of the tunable microwave circulator.
(C2) In the method denoted (C1), said generating includes determining an impedance mismatch between the impedance of the first input port and a nominal impedance of the first input port. Said generating also includes retrieving, based on the impedance mismatch, the correction signal from a look-up table.
(C3) In either of the methods denoted (C1) and (C2), the method further includes transmitting a signal from the second input port of the tunable microwave circulator to the third input port of the tunable microwave circulator via the second coupler of the tunable microwave circulator, the second amplifier of the tunable microwave circulator, and the third coupler of the tunable microwave circulator. The method also includes transmitting a signal from the third input port to the first input port via the third coupler, the third amplifier of the tunable microwave circulator, and the first coupler of the tunable microwave circulator.
(C4) In any of the methods denoted (C1) to (C3), said measuring the impedance of the first input port includes measuring a first impedance of the first input port, said generating the correction signal comprises generation a first correction signal, and said applying the correction signal comprises applying the first correction signal. The method further includes measuring a second impedance of the second input port of the tunable microwave circulator, generating a second correction signal based on the second impedance, and applying the second correction signal to the third variable impedance circuit of the tunable microwave circulator.
(C5) In the method denoted (C4), the method further includes measuring a third impedance of the third input port of the tunable microwave circulator, generating a third correction signal based on the third impedance, and applying the third correction signal to the first variable impedance circuit of the tunable microwave circulator.

1. A tunable microwave circulator, comprising:
a first coupler having a first input port, a first coupled port, a first transmitted port, and a first isolated port;
a first amplifier having an input connected to the first transmitted port;
a first variable impedance circuit connected to the first isolated port;
a second coupler having a second input port, a second coupled port connected to an output of the first amplifier, a second transmitted port, and a second isolated port;
a second amplifier having an input connected to the second transmitted port;
a second variable impedance circuit connected to the second isolated port;
a third coupler having a third input port, a third coupled port connected to an output of the second amplifier, a third transmitted port, and a third isolated port;
a third amplifier having an input connected to the third transmitted port and an output connected to the first coupled port; and
a third variable impedance circuit connected to the third isolated port.

2-3. (canceled)

4. The tunable microwave circulator of claim 1, further comprising:
an impedance sensor configured to measure an impedance of the first input port and output an impedance signal indicative of the impedance of the first input port;
a signal processor configured to process the impedance signal to generate a correction signal; and
a controller configured to output a control signal, based on the correction signal, to the second variable impedance circuit to control an impedance of the second variable impedance circuit.

5. The tunable microwave circulator of claim 4, the impedance sensor comprising a reflectometer.

6. The tunable microwave circulator of claim 5, the reflectometer comprising:
a transmission line;
a plurality of varactor diodes connected to the transmission line to sample the transmission line; and
an analog-to-digital converter configured to digitize a signal outputted by each of the plurality of varactor diodes.

7. The tunable microwave circulator of claim 6, further comprising a switch, wherein:
the switch, when in a first position, connects the first input port to the transmission line; and
the switch, when in a second position, connects the first input port to an external load.

8. The tunable microwave circulator of claim 4, wherein:
the signal processor comprises a memory storing a look-up table; and
the signal processor is configured to:
process the impedance signal to determine an impedance mismatch between the impedance of the first input port, as measured by the impedance sensor, and a nominal impedance of the first input port; and
retrieve, based on the impedance mismatch, the correction signal from the look-up table.

9. The tunable microwave circulator of claim 8, the signal processor comprising a field-programmable gate array in communication with the memory.

10. The tunable microwave circulator of claim 8, the signal processor comprising a microprocessor in communication with the memory, the memory storing machine-readable instructions that, when executed by the microprocessor, control the signal processor to process the impedance signal and retrieve the impedance correction.

11. The tunable microwave circulator of claim 1, further comprising:
a first impedance sensor configured to measure a first impedance of the first input port and output a first impedance signal indicative of the first impedance;
a signal processor configured to process the first impedance signal to generate a first correction signal;
a first controller configured to output a first control signal, based on the first correction signal, to the second variable impedance circuit to control an impedance of the second variable impedance circuit;
a second impedance sensor configured to measure a second impedance of the second input port and output a second impedance signal indicative of the second impedance, the signal processor being configured to process the second impedance signal to generate a second correction signal; and
a second controller configured to output a second control signal, based on the second correction signal, to the third variable impedance circuit to control an impedance of the third variable impedance circuit.

12. The tunable microwave circulator of claim 11, each of the first and second impedance sensors comprising a reflectometer.

13. The tunable microwave circulator of claim 11, wherein:
the signal processor comprises a memory storing a look-up table; and
the signal processor is configured to:
process the first impedance signal to determine a first impedance mismatch between the first impedance of the first input port, as measured by the first impedance sensor, and a first nominal impedance of the first input port;
retrieve, based on the first impedance mismatch, the first correction signal from the look-up table;
process the second impedance signal to determine a second impedance mismatch between the second impedance of the second input port, as measured by the second impedance sensor, and a second nominal impedance of the second input port; and
retrieve, based on the second impedance mismatch, the second correction signal from the look-up table.

14. The tunable microwave circulator of claim 11, further comprising:
a third impedance sensor configured to measure a third impedance of the third input port and output a third impedance signal indicative of the third impedance, the signal processor being configured to process the third impedance signal to generate a third correction signal; and
a third controller configured to output a third control signal, based on the third correction signal, to the first variable impedance circuit to control an impedance of the first variable impedance circuit.

15-16. (canceled)

17. The tunable microwave circulator of claim 1, further comprising one or more of:
a first controller configured to output a first control signal to the second variable impedance circuit to set an impedance of the second variable impedance circuit;
a second controller configured to output a second control signal to the third variable impedance circuit to set an impedance of the third variable impedance circuit; and
a third controller configured to output a third control signal to the first variable impedance circuit to set an impedance of the first variable impedance circuit.

18. The tunable microwave circulator of claim 1, further comprising one or more of:
a receiver connected to one of the first, second, and third input ports;
a transmitter connected to one of the first, second, and third input ports; and
an antenna connected to one of the first, second, and third input ports.

19-21. (canceled)

22. A tunable microwave circulator, comprising:
first, second, and third branches, each of the first, second, and third branches comprising:
a coupler having an input port, a coupled port, a transmitted port, and an isolated port;
an amplifier having an input connected to the transmitted port of the coupler; and
a variable impedance circuit connected to the isolated port of the coupler;
wherein:
an output of the amplifier of the first branch is connected to the coupled port of the coupler of the second branch;
an output of the amplifier of the second branch is connected to the coupled port of the coupler of the third branch; and
an output of the amplifier of the third branch is connected to the coupled port of the coupler of the first branch.

23. A method, comprising:
measuring an impedance of the first input port of the tunable microwave circulator of claim 1;
generating a correction signal based on the impedance; and
applying the correction signal to the second variable impedance circuit of the tunable microwave circulator.

24. The method of claim 23, wherein said generating comprises:
determining an impedance mismatch between the impedance of the first input port and a nominal impedance of the first input port; and
retrieving, based on the impedance mismatch, the correction signal from a look-up table.

25. The method of claim 23, further comprising:
transmitting a signal from the second input port of the tunable microwave circulator to the third input port of the tunable microwave circulator via the second coupler of the tunable microwave circulator, the second amplifier of the tunable microwave circulator, and the third coupler of the tunable microwave circulator; and
transmitting a signal from the third input port to the first input port via the third coupler, the third amplifier of the tunable microwave circulator, and the first coupler of the tunable microwave circulator.

26. The method of claim 23, wherein:
measuring the impedance of the first input port comprises measuring a first impedance of the first input port;
generating the correction signal comprises generating a first correction signal;
applying the correction signal comprises applying the first correction signal; and
the method further comprises:
measuring a second impedance of the second input port of the tunable microwave circulator;
generating a second correction signal based on the second impedance; and
applying the second correction signal to the third variable impedance circuit of the tunable microwave circulator.

27. The method of claim 26, further comprising:
measuring a third impedance of the third input port of the tunable microwave circulator;
generating a third correction signal based on the third impedance; and
applying the third correction signal to the first variable impedance circuit of the tunable microwave circulator.
